(19) United States
(12) Patent Application Publication
(10) Pub. No.: US 2017/0290185 A1
(43) Pub. Date: Oct. 5, 2017

(54) HOUSING STRUCTURE OF ELECTRONIC DEVICE

(71) Applicant: FUJITSU TEN LIMITED, Kobe-shi (JP)

(72) Inventors: Yuji OHNO, Takatsuki-shi (JP); Nobumasa TOKUI, Kobe-shi (JP); Teruo TAKENAKA, Kobe-shi (JP); Junichi ENDO, Kobe-shi (JP)

(73) Assignee: FUJITSU TEN LIMITED, Kobe-shi (JP)

(21) Appl. No.: 15/453,023

(22) Filed: Mar. 8, 2017

(30) Foreign Application Priority Data
Mar. 31, 2016 (JP) 2016-071299

(51) Int. Cl. H05K 7/14; H05K 1/18

(52) U.S. Cl. CPC H05K 7/1427; H05K 1/181

(57) ABSTRACT

A housing structure of an electronic device according to an embodiment includes a housing and a protruding part. The housing houses a board on which an electronic part is mounted. The protruding part protrudes toward the board from an upper side of the housing positioned above the board. An inner wall of the housing has a groove that is formed around the protruding part.

### CROSS-REFERENCE TO RELATED APPLICATION

This application is based upon and claims the benefit of priority of the prior Japanese Patent Application No. 2016-071299, filed on Mar. 31, 2016, the entire contents of which are incorporated herein by reference.

### FIELD

The embodiment discussed herein is directed to a housing structure of an electronic device.

### BACKGROUND

Conventionally, among housings that house boards with electronic parts mounted thereon, there is known a housing whose upper inner surface is inclined to the horizontal plane when the housing is mounted (for example, see Japanese Laid-open Patent Publication No. 2003-229678).

The aforementioned housing can prevent, because condensed water on the upper inner surface generated by temperature difference between the inside and outside of the housing flows along the inclined inner surface, the condensed water generated on the upper inner surface from dropping onto the board.

The aforementioned housing has, in some cases, for example, a protruding part for attaching the board to the housing, which is provided toward the board from the upper inner surface. Such a housing has a fear that condensed water generated on the upper inner surface moves down along the protruding part to attach to the board from a leading end of the protruding part. Thus, the aforementioned housing does not consider a case where the condensed water is attached to the board by way of the protruding part. Therefore, there exists a fear that the condensed water generated on the upper inner surface attaches to the board by way of the protruding part to cause a short circuit of the board due to the attached condensed water.

### SUMMARY

A housing structure of an electronic device according to an embodiment includes a housing and a protruding part. The housing houses a board on which an electronic part is mounted. The protruding part protrudes toward the board from an upper side of the housing positioned above the board. An inner wall of the housing has a groove that is formed around the protruding part.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic view illustrating an interior of a vehicle mounted thereon an electronic device according to a present embodiment;

FIG. 2 is a schematic view illustrating the interior of the vehicle from a side view;

FIG. 3 is a plan view illustrating the electronic device according to the present embodiment;

FIG. 4 is a cross-sectional view taken along a line IV-IV illustrated in FIG. 3;

FIG. 5 is a bottom view illustrating the electronic device according to the present embodiment;

FIG. 6 is an enlarged perspective view illustrating a boss according to the present embodiment; and

FIGS. 7 to 9 are diagrams illustrating modifications of the present embodiment.

### DESCRIPTION OF EMBODIMENTS

The outline of a housing structure of an electronic device according to the present embodiment will be explained with reference to accompanying drawings. Hereinafter, a housing structure of housing an air-bag Electronic Control Unit (air-bag ECU) mounted on a vehicle to cause an air-bag to operate will be explained as an example, however, is not limited thereto.

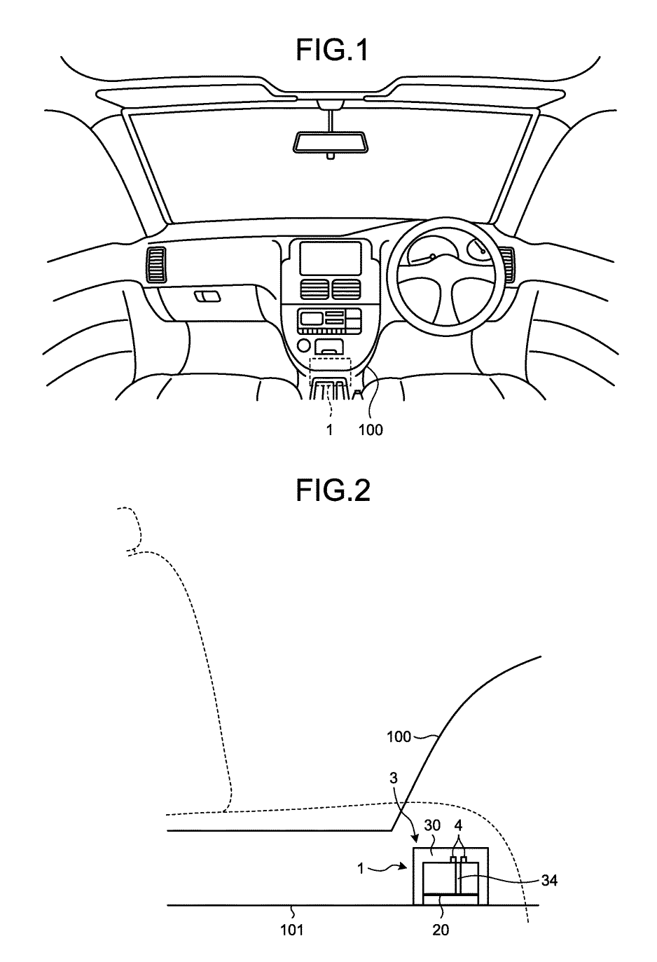

FIG. 1 is a schematic view illustrating an interior of a vehicle mounted thereon an electronic device according to a present embodiment. FIG. 2 is a schematic view illustrating the interior of the vehicle from a side view. In FIG. 2, a seat is illustrated by using dashed lines.

An electronic device 1 is arranged under a center console 100 of a vehicle. Specifically, the electronic device 1 is arranged on a center tunnel 101 positioned under the center console 100 while placing a silencer (not illustrated) therebetween, and mounted on the center tunnel 101 by using a bolt (not illustrated), etc.

Thus, the electronic device 1 is mounted at a comparatively low position of the vehicle. Therefore, for example, when drinking water spills to wet the center console 100, there exists a fear that the drinking water soaks the peripheral of the electronic device 1 from a gap and the like of members constituting the center console 100. In the periphery of the electronic device 1, a pipe (not illustrated) of a vehicle air conditioner and the like are arranged. Thereby, when dew condensation is generated outside of the pipe of the vehicle air conditioner, there exists a fear that the periphery of the electronic device 1 is moistened by the condensed water. For example, a drip-proof sheet (not illustrated) made of flexible vinyl is pasted on an upper part of the electronic device 1 to prevent liquid such as drinking water from directly falling on the electronic device 1.

Thus, when the humidity in the periphery of the electronic device 1 increases, high humidity air goes into the electronic device 1 from, for example, a gap between members of the electronic device 1 and the like, and the humidity in the electronic device 1 increases in some cases.

In such a state, when temperature difference between the inside and outside of the electronic device 1 increases and the temperature outside of the electronic device 1 is higher than the temperature inside of the electronic device 1, dew condensation is generated on an inner wall of the electronic device 1.

In the electronic device 1, a board 20 is attached to bosses 34 protruding from an upper surface 30 of a housing 3. In the electronic device 1 mounted on the vehicle, the condensed water easily moves by a slope of a road surface, the vibration of the vehicle, etc., and thus a drop (hereinafter, may be simply referred to as “condensed water”) to be formed by the condensed water easily grows to a large size. Therefore, the grown condensed water moves down along the bosses 34 to attach to the board 20 in some cases. In this way, when the condensed water attaches to the board 20, there exists a fear that the board 20 short-circuits caused by the attached condensed water.

In the present embodiment, grooves 4 are formed in the periphery of the bosses 34 to prevent the condensed water from attaching to the bosses 34, and further to prevent the condensed water from moving down along the bosses 34. Thereby, it is possible to prevent the condensed water from attaching to the board 20, so that it is possible to improve the reliability of the board 20.

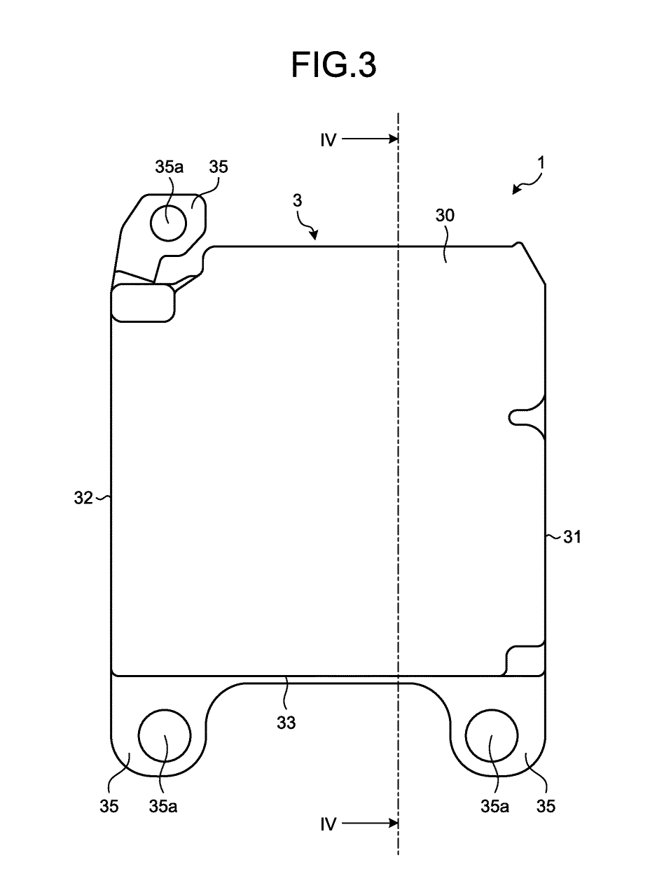

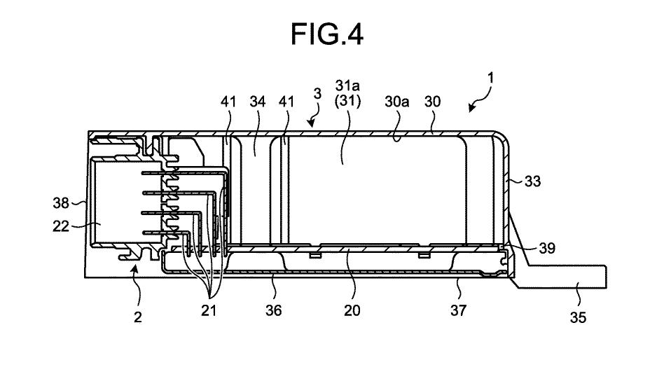

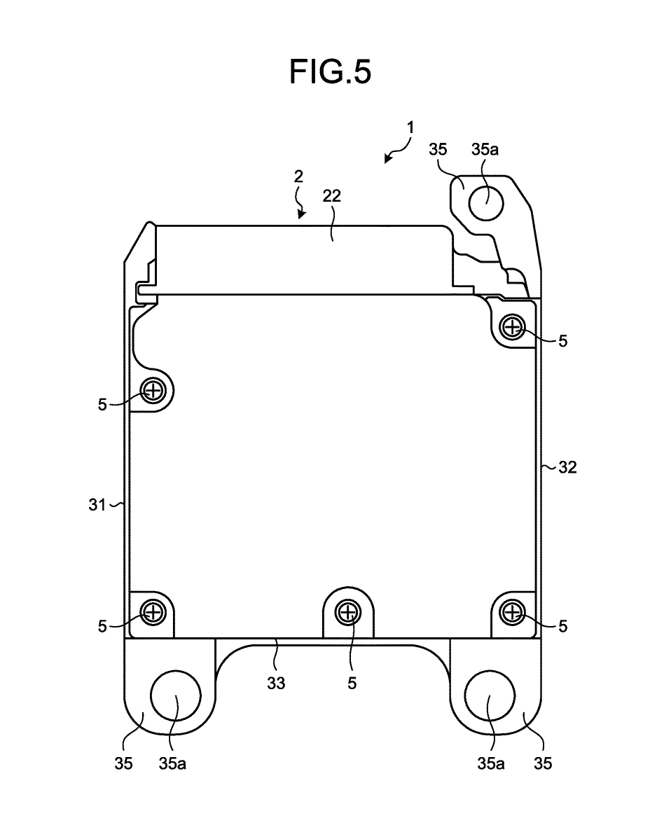

Next, the electronic device 1 will be specifically explained with reference to FIGS. 3 to 5. FIG. 3 is a plan view illustrating the electronic device 1. FIG. 4 is a cross-sectional view taken along a line IV-IV illustrated in FIG. 3. FIG. 5 is a bottom view illustrating the electronic device 1.

The electronic device 1 includes an air-bag ECU 2 and the housing 3 housing the air-bag ECU 2.

The air-bag ECU 2 includes the board 20, connectors 21, and a connector case 22.

An electronic part such as a microcomputer is attached on the board 20. The board 20 is attached to the bosses 34 (to be mentioned later) of the housing 3 by using a plurality of screws 5.

The connectors 21 electrically connect a circuit of the board 20 to a satellite sensor provided outside, a gas generating device, etc. The connectors 21 are held by the connector case 22.

The connector case 22 is provided so as to block a second opening 38 (to be mentioned later) formed on the housing 3.

The housing 3 includes the upper surface 30, a first side surface 31, a second side surface 32, a third side surface 33, the bosses 34, attaching parts 35, and a lid 36.

The upper surface 30 opposes the board 20, and is positioned above the board 20 in such a state that the electronic device 1 is mounted on the vehicle. A roughening treatment that is a hydrophilic treatment is applied to an inner wall 30a of the upper surface 30. Specifically, a sandblast process is applied to the inner wall 30a of the upper surface 30 as the roughening treatment. The plurality of bosses 34 protruding toward the board 20 are formed in an edge side of the upper surface 30. Details of the bosses 34 and the periphery of the bosses 34 will be mentioned later.

The first side surface 31, the second side surface 32, and the third side surface 33 extend down from respective three edge sides of the upper surface 30 to be formed. The first side surface 31 and the second side surface 32 are formed so that they oppose each other while placing the board 20 therebetween. The third side surface 33 is formed to connect the first side surface 31 to the second side surface 32. Any of the first side surface 31, the second side surface 32, and the third side surface 33 is not attached to the board 20. In other words, predetermined gaps 39 are formed between the first side surface 31 and the board 20, between the second side surface 32 and the board 20, and between the third side surface 33 and the board 20, respectively. The predetermined gaps 39 are formed so that condensed water does not attach to the board 20 in a case where the condensed water flows down along the first side surface 31, the second side surface 32, and the third side surface 33.

Thus, the first side surface 31, the second side surface 32, and the third side surface 33 extend down from the respective three edge sides of the upper surface 30 to form the housing 3. Moreover, as illustrated in FIG. 4, in the housing 3, the first opening 37 is formed at a position opposing the upper surface 30 and the second opening 38 is formed at a position opposing the third side surface 33. In other words, the shape of the housing 3 is a roughly rectangular parallelepiped having two openings (first opening 37 and second opening 38).

The air-bag ECU 2 of the electronic device 1 is attached to the housing 3 so that the connector case 22 blocks the second opening 38 of the housing 3. The lid 36 of the electronic device 1 is arranged under the board 20 so that the lid 36 blocks the first opening 37 of the housing 3, and the board 20 and the lid 36 are attached to the bosses 34 of the housing 3 at a plurality of spots by using the screws 5.

The structure of the electronic device 1 is not a structure of sealing the inside of the housing 3 by using the connector case 22 and the lid 36, and air enters or leaves between the outside and inside of the electronic device 1.

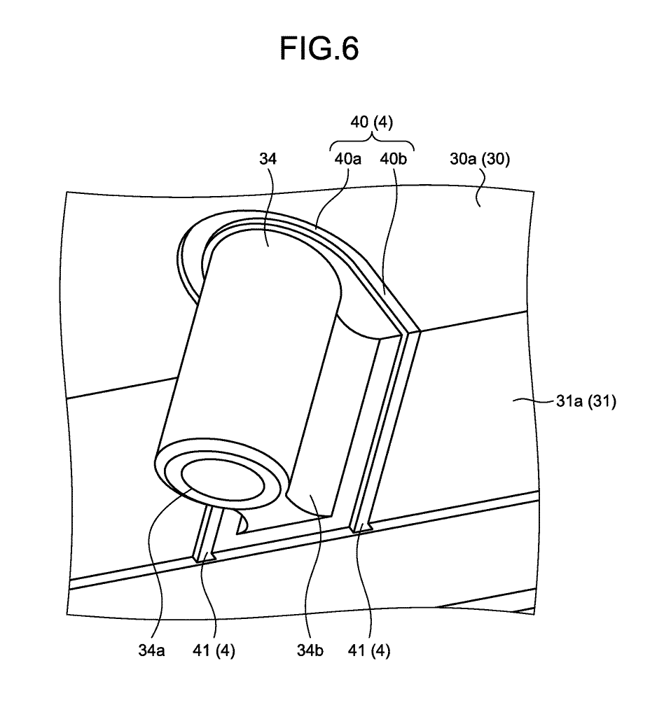

Next, a configuration of the periphery of one of the bosses 34 will be specifically explained with reference to FIG. 6. FIG. 6 is an enlarged perspective view illustrating the boss 34 seen from the board 20 side.

The boss 34 protrudes toward the board 20 from the inner wall 30a of the upper surface 30. The boss 34 is roughly cylindrical. A attaching hole 34a is formed at the leading end of the boss 34 on the board 20 side so that the board 20 and the lid 36 can be attached from beneath by using the screw 5. The plurality of bosses 34 are formed on an edge side of the upper surface 30. The boss 34 includes a connection part 34b connected to the first side surface 31, the second side surface 32, or the third side surface 33, which is adjacent thereto. In other words, each of the bosses 34 protrudes toward the board 20 from the upper surface 30 while being connected to one of the first side surface 31, the second side surface 32, and the third side surface 33 by the connection part 34b.

Hereinafter, the boss 34 connected to the first side surface 31 will be explained as an example, the case of the boss 34 connected to the second side surface 32 or the third side surface 33 is similar thereto.

A first groove 40 is formed on the inner wall 30a of the upper surface 30 in the periphery of the boss 34. A second grooves 41 are formed on an inner wall 31a of the first side surface 31 in the periphery of the boss 34. The second grooves 41 are connected to the first groove 40, and the one groove 4 is formed by the first groove 40 and the second grooves 41.

The first groove 40 is formed along the boss 34 so that the area of the inner wall 30a of the upper surface 30 between the first groove 40 and the boss 34 is small. Specifically, the first groove 40 is formed so that, even when dew condensation is generated on the inner wall 30a of the upper surface 30 between the boss 34 and the first groove 40, condensed water generated in this region does not grow to a large size to move to the under part of the boss 34 along the boss 34. The depth, width, and shape of the first groove 40 are set so that, when condensed water flows into the first groove 40, the condensed water does not arrive at the boss 34 across the first groove 40. Specifically, the first groove 40 is formed so that the shape of the cross-section thereof is rectangular shape.

The first groove 40 is formed so as to extend up to the first side surface 31 along the boss 34. The first groove 40 is formed by an arc-shaped groove 40a that is formed in accordance with the shape of an outer peripheral wall of the boss 34 and linear-shaped grooves 40b connected to the arc-shaped groove 40a. It is desirable that the curvature of the arc-shaped groove 40a is small while preventing condensed water generated in the inner wall 30a of the upper surface 30 between the first groove 40 and the bosses 34 from growing to a large size as described above. The linear-shaped grooves 40b is extended in a tangential direction of the arc-shaped groove 40a to be formed. By employing this form of the first groove 40, the drainage property of condensed water when the condensed water flows into the first groove 40 can be improved, and thus it is possible to prevent the condensed water from dropping onto the board 20 from the first groove 40. Moreover, it is possible to prevent the condensed water from arriving at the boss 34 across the first groove 40.

The second grooves 41 are formed into the linear shape along the connection part 34b of the boss 34. Similarly to the first groove 40, even when dew condensation is generated on the inner wall 31a of the first side surface 31 between the boss 34 and the second groove 41, the second groove 41 is formed so that condensed water generated in this region does not grow to a large size to move to the under part of the boss 34 along the boss 34. The depth, width, and shape of the second groove 41 are set so that, even when condensed water flows into the second groove 41, the condensed water does not arrive at the boss 34 across the second groove 41.

A hydrophilic treatment is not applied to the first groove 40 and the second grooves 41 to improve the drainage property when condensed water flows into the groove 4.

Returning to FIGS. 3 to 5, the attaching parts 35 are formed so as to extend outside from the second side surface 32 or the third side surface 33. Bolts (not illustrated) are inserted into respective attaching apertures 35a of the attaching parts 35 to be fixed by nuts (not illustrated), and thus the electronic device 1 is mounted on the center tunnel 101 (see FIG. 2).

In the present embodiment, the groove 4 (first groove 40 and second grooves 41) is provided in the periphery of the boss 34, and thus the groove 4 can prevent condensed water from flowing to the boss 34 even when dew condensation is generated on the inner wall 30a of the upper surface 30 of the housing 3. Thereby, it is possible to prevent the condensed water flowed along the boss 34 from attaching to the board 20. Therefore, short circuit of the board 20 caused by condensed water can be prevented, so that it is possible to improve the reliability of the board 20.

The first groove 40 is extended up to the side surface (first side surface 31, second side surface 32, or third side surface 33; the same applies hereafter), and thus, when condensed water flows into the first groove 40, the condensed water can be guided to the side surface by the first groove 40, so that it is possible to drain the condensed water. Thereby, it is possible to prevent the condensed water flowed along the boss 34 from attaching to the board 20. Therefore, short circuit of the board 20 caused by condensed water can be prevented, so that it is possible to improve the reliability of the board 20. Moreover, even when the condensed water flows on the side surface, because the predetermined gap 39 is formed between the side surface and the board 20, the condensed water flowing on the side surface does not attach to the board 20 from the side surface.

The groove 4 is formed along the boss 34, and thereby growth of condensed water to a large size on the inner wall 30a of the upper surface 30 between the first groove 40 and the boss 34, and on the inner wall of the side surface between the second groove 41 and the boss 34 can be prevented, and thus it is possible to prevent the condensed water flowed along the boss 34 from attaching to the board 20. Therefore, short circuit of the board 20 caused by condensed water can be prevented, so that it is possible to improve the reliability of the board 20.

The first groove 40 is formed on the upper surface 30 in the periphery of the boss 34, the second grooves 41 are formed on the side surface in the periphery of the boss 34, and the first groove 40 and the second grooves 41 are connected to each other to form the one groove 4. Thereby, when condensed water flows into the groove 4, the groove 4 can drain the condensed water to prevent the condensed water from flowing to the bosses 34, and thus it is possible to prevent the condensed water flowed along the boss 34 from attaching to the board 20. Therefore, short circuit of the board 20 caused by condensed water can be prevented, so that it is possible to improve the reliability of the board 20.

For example, when the first groove 40 is formed into the S-shape, there exists a fear that condensed water grows to a large size to drop on the board 20 because the condensed water easily stands in the S-shaped part. The first groove 40 according to the present embodiment is formed by the arc-shaped groove 40a and the linear-shaped grooves 40b extended in a tangential direction of the arc-shaped groove 40a. Thereby, even when condensed water flows into the first groove 40, the condensed water flowed into the first groove 40 hardly stands, and thus the drainage property of condensed water can be improved, so that it is possible to prevent condensed water from dropping onto the board 20. Therefore, short circuit of the board 20 caused by condensed water can be prevented, so that it is possible to improve the reliability of the board 20.

Moreover, the application of a roughening treatment that is a hydrophilic treatment to the inner wall 30a of the upper surface 30 of the housing 3 can prevent condensed water from growing to a large size on the inner wall 30a of the upper surface 30. Thereby, it is possible to prevent condensed water from dropping onto the board 20, and thus short circuit of the board 20 caused by the condensed water can be prevented, so that it is possible to improve the reliability of the board 20.

The electronic device 1 according to the present embodiment is mounted on the vehicle. Therefore, condensed water easily moves, and thus easily grows to a large size caused by a slope of a road surface or the vibration of the vehicle. Thereby, even in a case where a hydrophilic treatment is applied to the inner wall 30a of the upper surface 30, condensed water easily flows along the boss 34 to attach to the board 20. In the present embodiment, a roughening treatment is applied to the inner wall 30a of the upper surface 30 and the groove 4 is formed in the periphery of the boss 34, and thus it is possible to prevent the condensed water flowed along the boss 34 from attaching to the board 20, so that short circuit of the board 20 caused by the condensed water can be prevented.

By employing application of a sandblast process as a roughening treatment, a hydrophilic treatment can be applied to the inner wall 30a of the upper surface 30 by using a simple process.

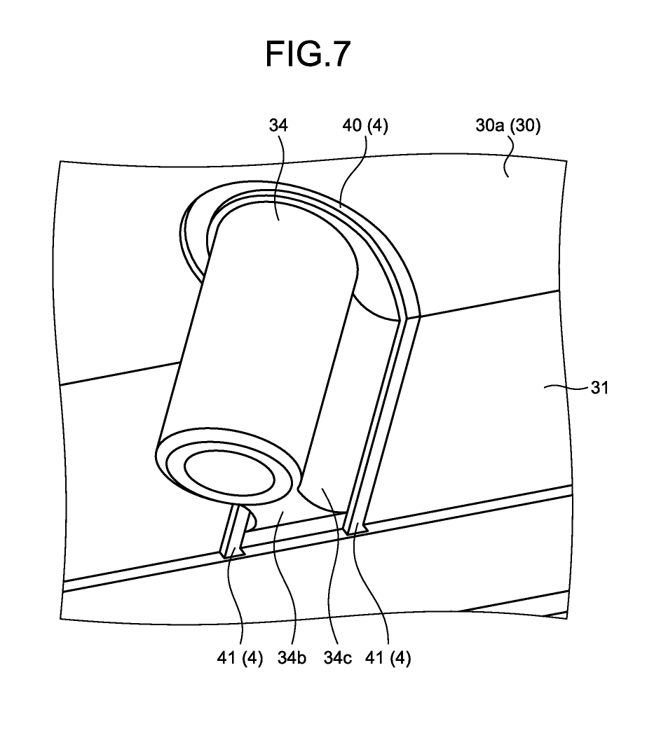

Next, a modification of the present embodiment will be explained with reference to FIG. 7. FIG. 7 is an enlarged perspective view illustrating the boss 34 seen from the board 20 side.

In this modification, the second grooves 41 are formed on side surfaces 34c of the connection part 34b. The boss 34 connected to the first side surface 31 by the connection part 34b is illustrated in FIG. 7, the case of the boss 34 connected to the second side surface 32 or the third side surface 33 is similar thereto.

In this modification, an inner wall of the side surface between the second groove 41 and the connection part 34b does not exist. Therefore, condensed water is not generated on the inner wall of the side surface between the second groove 41 and the connection part 34b. Moreover, in this modification, the area of the inner wall 30a of the upper surface 30 between the first groove 40 and the boss 34 can be small, and thus condensed water to be generated in this region can be reduced. Thereby, flow of condensed water to the boss 34 from the side surface and the upper surface 30 can be prevented more reliably, and thus attachment of the condensed water flowed along the boss 34 to the board 20 can be prevented more reliably. Therefore, short circuit of the board 20 caused by condensed water can be prevented more reliably, so that it is possible to more improve the reliability of the board 20.

As an additional modification, a part of the second groove 41 may be formed on the side surface 34c of the connection part 34b. In other words, grooves may be formed on the side surface 34c of the connection part 34b and an inner wall of the side surface, respectively, and these grooves may be connected to each other to form the second groove 41. Thereby, the area of the inner wall 30a of the upper surface 30 between the boss 34 and the first groove 40 can be small, and thus growth of condensed water to a large size in this region can be prevented. Therefore, it is possible to prevent condensed water from flowing to the boss 34 more reliably, and thus it is possible to prevent the condensed water flowed along the boss 34 from attaching to the board 20 more reliably. Therefore, short circuit of the board 20 caused by condensed water can be prevented more reliably, so that it is possible to more improve the reliability of the board 20.

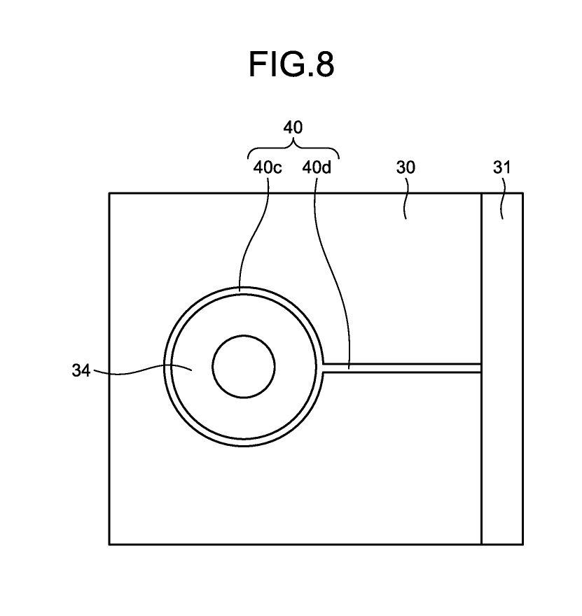

Next, a modification of the present embodiment will be explained with reference to FIG. 8. FIG. 8 is a schematic view illustrating the boss 34 seen from the board 20 side.

In this modification, the boss 34 is formed at a position that is apart from an edge side of the upper surface 30, for example, near the center of the upper surface 30, the boss 34 is not connected to the side surface, and only the first groove 40 is formed. The first groove 40 is formed so as to extend up to the first side surface 31 along the boss 34. Specifically, the first groove 40 is formed by a circular-shaped groove 40c and linear-shaped groove 40d connected to the circular-shaped groove 40c. The first groove 40 extended up to the first side surface 31 is illustrated in FIG. 8, may be extended up to the second side surface 32 or the third side surface 33.

In this modification, when condensed water flows into the circular-shaped first groove 40, the condensed water can be guided to the side surface by the linear-shaped groove 40d, so that it is possible to drain the condensed water. Thereby, it is possible to prevent the condensed water flowed along the boss 34 from attaching to the board 20. Therefore, short circuit of the board 20 caused by condensed water can be prevented, so that it is possible to improve the reliability of the board 20.

As an additional modification, a plurality of linear-shaped grooves 40d may be formed in the first groove 40. For example, the plurality of linear-shaped grooves 40d may be extended in tangential directions of the circular-shaped groove 40c to form the first groove 40. The plurality of linear-shaped grooves 40d may extend up to the same side surface, or may extend up to the different side surfaces. Thereby, in a case where the electronic device 1 is inclined to the horizontal direction, for example, a case where the vehicle is inclined, condensed water can be guided to the side surface, and thus the condensed water can be drained.

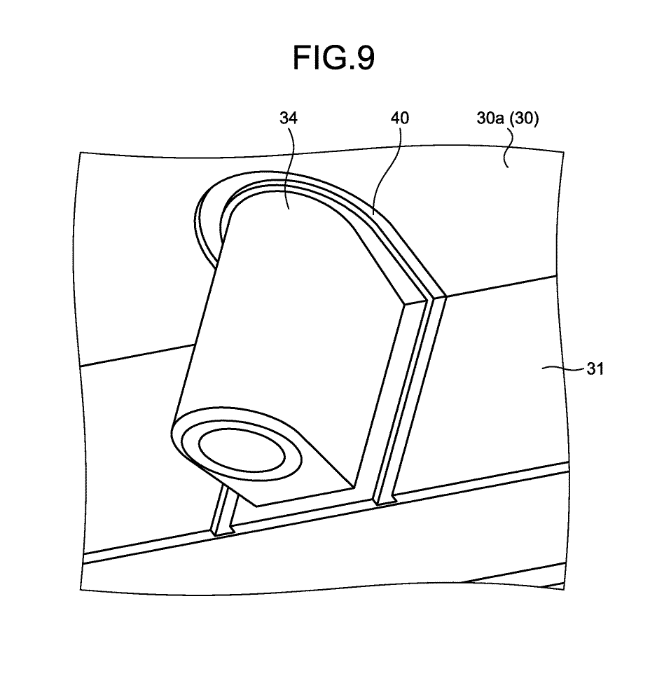

Next, a modification of the present embodiment will be explained with reference to FIG. 9. FIG. 9 is an enlarged schematic view illustrating the boss 34 seen from the board 20 side.

In this modification, the boss 34 extends up to the side surface to be connected thereto without providing the connection part 34b. Specifically, the boss 34 extends in a tangential direction from an outer peripheral wall of the cylindrical-shaped boss 34, and thus the boss 34 is connected to the side surface. The boss 34 connected to the first side surface 31 is illustrated in FIG. 9, the boss 34 connected to the second side surface 32 or the third side surface 33 is similar thereto. As in this modification, the first groove 40 may be formed along the boss 34.

In this modification, the area of the inner wall 30a of the upper surface 30 between the boss 34 and the first groove 40 can be smaller without changing the shape of the first groove 40. In other words, the area of the inner wall 30a of the upper surface 30 between the boss 34 and the first groove 40 can be small while keeping the drainage property of condensed water flowed into the first groove 40. Therefore, growth of the condensed water to a large size on the inner wall 30a of the upper surface 30 between the boss 34 and the first groove 40 can be prevented more reliably. Therefore, it is possible to prevent the condensed water flowed along the boss 34 from attaching to the board 20, and thus the reliability of the board 20 can be more improved.

As an additional modification, the boss 34 and the side surface may be integrally formed. In other words, the side surface may be formed so that the thickness thereof is large, the attaching hole 34a may be formed in the part whose thickness is large, and the board 20 may be attached thereto. Thereby, the curvature of the first groove 40 becomes small, and thus the drainage property of the first groove 40 can be more improved.

In the aforementioned embodiment, a sandblast process is applied as a roughening treatment, however, a grooving process, the embossing, or the like other than the sandblast process may be applied to the inner wall 30a of the upper surface 30. The roughening treatment may be applied by using a mold whose molding face is roughened. The hydrophilic treatment may be applied to the inner wall 30a of the upper surface 30 by using a process of putting on a hydrophilic coating agent, pasting a hygroscopic member, etc.

The hydrophilic treatment may be applied to not only the inner wall 30a of the upper surface 30 of the housing 3, but also the side surface of the housing 3. Thereby, condensed water to be generated on the inner wall 30a of the upper surface 30 can be reduced, attachment to the board 20 by the condensed water generated on the upper surface 30 can be prevented more reliably, short circuit of the board 20 caused by condensed water can be prevented more reliably, so that it is possible to more improve the reliability of the board 20. The hydrophilic treatment may be applied to the boss 34. The hydrophilic treatment may be applied to the first groove 40 and the second groove 41. The application of the hydrophilic treatment to the first groove 40 can prevent the condensed water flowed from the first groove 40 from dropping.

No hydrophilic treatment may be applied to the inner wall 30a of the upper surface 30 of the housing 3, the application of the hydrophilic treatment thereto can prevent condensed water from attaching to the board 20, so that short circuit of the board 20 caused by the condensed water can be prevented more reliably.

In the aforementioned embodiment, the groove 4 is formed in the periphery of the boss 34, the groove 4 may be formed at a part protruding toward the board 20 from the upper surface 30, for example, in the periphery of a rib. In other words, the groove 4 is provided in the periphery of a protruding part protruding toward the board 20 from the upper surface 30. The groove 4 may be formed in the periphery of, not the protruding part protruding from the upper surface 30, but a protruding part protruding toward the board 20 from the side surface that is positioned upper than the board 20. Thereby, it is possible to prevent condensed water from flowing to a protruding part, and thus attachment of the condensed water flowed along the protruding part to the board 20 can be prevented. Therefore, short circuit of the board 20 caused by condensed water can be prevented, so that it is possible to improve the reliability of the board 20.

The cross-section of the first groove 40 may be formed into V-shape whose width decreases toward the upper part, or U-shape. Thereby, when condensed water flows into the first groove 40, it is possible to prevent the condensed water from dropping onto the board 20 from the first groove 40. A wall surface of the groove closer to the boss 34 may be formed so that the wall surface is perpendicular to a bottom of the groove and a wall surface of the groove further from the boss 34 may be formed so that the wall surface is tapered. Thereby, condensed water generated on the upper surface 30 can be guided to the first groove 40, growth of the condensed water to a large size on the upper surface 30 can be prevented, and it is possible to prevent condensed water flowed into the first groove 40 from moving toward the boss 34 more reliably.

According to one aspect of the embodiment, it is possible to prevent condensed water generated in a housing from attaching to a board.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents. For example, in the aforementioned embodiment, the example in which the vehicle controller 30 specifies an abnormal part is explained, not limited thereto, the power-supply monitoring device 23 may execute the specifying.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A housing structure of an electronic device, the structure comprising:
a housing that houses a board on which an electronic part is mounted; and
a protruding part that protrudes toward the board from an upper side of the housing positioned above the board, wherein
an inner wall of the housing has a groove that is formed around the protruding part.

2. The housing structure of the electronic device according to claim 1, wherein the groove is formed on an inner wall of an upper surface of the housing positioned above the board, and extends up to a side surface of the housing connected to the upper surface.

3. The housing structure of the electronic device according to claim 2, wherein the groove is formed of an arc-shaped groove and a linear-shaped groove, the linear-shaped groove being connected to the arc-shaped groove and extending in a tangential direction of the arc-shaped groove.

4. The housing structure of the electronic device according to claim 1, wherein the groove is formed along the protruding part.

5. The housing structure of the electronic device according to claim 1, wherein
the protruding part protrudes toward the board from an upper surface of the housing positioned above the board, and is connected to a side surface of the housing connected to the upper surface, and
the groove is formed of a first groove formed on an inner wall of the upper surface along the protruding part and a second groove connected to the first groove and formed on an inner wall of the side surface of the housing along the protruding part.

6. The housing structure of the electronic device according to claim 1, wherein
the protruding part protrudes toward the board from an upper surface of the housing positioned above the board, and is connected to a side surface of the housing connected to the upper surface, and
the groove is formed of a first groove formed on an inner wall of the upper surface along the protruding part and a second groove connected to the first groove and formed on a side surface of the protruding part connected to the side surface of the housing along the protruding part.

7. The housing structure of the electronic device according to claim 1, wherein a hydrophilic treatment is applied to the inner wall of the housing positioned above the board.

8. The housing structure of the electronic device according to claim 7, wherein the hydrophilic treatment includes a roughening treatment.
